(19) United States
(12) Patent Application Publication
(10) Pub. No.: US 2005/0273677 A1
(43) Pub. Date: Dec. 8, 2005

(54) Circuit and method for storing a signal using a latch shared between operational and diagnostic paths

(75) Inventors: Martin Jay Kinkade, Austin, TX (US); Marlin Frederick JR., Cedar Park, TX (US)

Correspondence Address: NIXON & VANDERHYE, PC, 901 NORTH GLEBE ROAD, 11TH FLOOR, ARLINGTON, VA, 22203, US

(73) Assignee: ARM LIMITED, Cambridge (GB)

(21) Appl. No.: 10/860,643

(22) Filed: Jun. 4, 2004

(51) Int. Cl. G11C 29/00

(52) U.S. Cl. 714/718

(57) ABSTRACT

A circuit 2 for storing a signal value includes an operational data path formed by an operational path latch 4 and a shared latch 6. A diagnostic data path is formed by a diagnostic path latch 12 and the shared latch 6. An operational clock signal CLK controls the operational path and a diagnostic clock signal SCLK controls the diagnostic path. When the operational clock signal CLK is active in the operational mode, the diagnostic clock signal SCLK is held at a predetermined value to disable the diagnostic data path and enable action of the shared latch as part of the operational data path. Conversely, in the diagnostic mode, the diagnostic clock signal SCLK is active and the operational clock signal CLK is held at a predetermined value to disable the operational data path and enable the shared latch 6 as part of the diagnostic data path.

### BACKGROUND OF THE INVENTION

1. Field of the Invention

This invention relates to the field of data processing systems. More particularly, this invention relates to circuits and methods within such data processing systems that serve to store signal values.

2. Description of the Prior Art

It is known to provide integrated circuits with flip-flop circuits therein that store signal values during an operational mode and also during a diagnostic mode. In the operational mode the signal values are stored within the flip-flop as they propagate through the integrated circuit undergoing various data processing operations. For diagnostic purposes, it is known to capture such signal values from the flip-flops and then serially clock these out from the integrated circuit using a serial scan chain. As the number of signal values which need to be latched and potentially scanned out of the integrated circuit is large, and steadily increasing as integrated circuits increase in complexity, it is desirable that the flip-flop circuitry should be efficient in terms of the number of gates used as it is replicated many thousands of times throughout the integrated circuit.

A known form of flip-flop which serves to latch data during an operational mode and also during a diagnostic mode is one in which phase 1 and phase 2 latches are disposed downstream of a multiplexer which selects between operational data and serial scan chain diagnostic data. When data capture is required, the signal value already within the latch will serve as the captured value for that latch. This captured value will then be scanned out through other similar flip-flops for which the multiplexer selects as its input the output of a previous flip-flop circuit so as to form a serial scan chain.

A problem with this design is that the multiplexer which is required in front of the flip-flop imposes a disadvantageous signal path delay. As the total path delay between nodes (flip-flops storing signal values) is decreased with the move towards higher clock frequencies, then the signal path delay imposed by the multiplexing circuit becomes an increasing proportion of the total signal path delay. The role of the multiplexing circuit is to provide appropriate switching for infrequent use in the diagnostic mode of operation and yet it imposes a significant signal path delay during an operational mode on what can be a critical signal path within the integrated circuit.

### SUMMARY OF THE INVENTION

Viewed from one aspect the present invention provides a circuit for storing a signal value, said circuit comprising:
an operational clock signal source operable in an operational mode to provide an operational clock signal having a first operational clock phase and a second operational clock phase;
an operational data path including:
   an operational path latch operable to receive a signal value during said second operational clock phase and to store said signal value during said first operational clock phase; and
   a shared latch coupled to said operational path latch and operable to receive said signal value during said first operational clock phase and to store said signal value during said second operational clock phase;
a diagnostic clock signal source operable in a diagnostic mode to provide a diagnostic clock signal having a first diagnostic clock phase and a second diagnostic clock phase; and
a diagnostic data path including:
   a diagnostic path latch operable to receive a signal value during said second diagnostic clock phase and to store said signal value during said first diagnostic clock phase; and
   said shared latch coupled to said diagnostic path latch and operable to receive said signal value during said first diagnostic clock phase and to store said signal value during said second diagnostic clock phase.

The present technique recognises the disadvantage associated with the multiplexer used in the prior art designs and seeks to remove this by providing at least partially separate latching circuits for the operational and diagnostic data paths. The present technique combines this removal of the multiplexer with the use of the shared latch which is shared between both the operational and diagnostic data paths so as to reduce the overall gate count of the flip-flop circuitry compared to providing completely separate latches and also to provide an arrangement whereby the signal value to be captured from the operational mode is already present within the shared latch when the flip-flop switches into the diagnostic mode.

It will be appreciated that the second phase and the first phase of both the operational clock and the diagnostic clock do not imply any particular clock signal level. Furthermore, it will be appreciated that in its general sense the invention is equally applicable to embodiments in which the shared latch either precedes or follows the dedicated latch in either or both of the operational data paths and the diagnostic data path.

A particularly preferred way of implementing the shared latch is in the form of a first tristate driver which is selectively enabled by the operational clock signal and a second tristate driver which is selectively enabled by the diagnostic clock signal. This provides a functionally symmetric arrangement whereby the two tristate drivers can swap their roles with one being switched on and the other selectively switched on by its appropriate clock signal depending upon the current operational mode of the flip-flop.

The switching between the different modes of operation may be advantageously achieved in embodiments in which the operational clock signal is held static when the diagnostic clock signal is active and the diagnostic clock signal is held static when the operational clock signal is active.

It will be appreciated that the diagnostic data path could take a variety of different forms and is not limited to serial scan chains. However, the invention is particularly useful in the context of integrated circuits when the diagnostic data path is part of a serial scan chain for serially scanning diagnostic data through the integrated circuit.

In order to reduce power consumption preferred embodiments provide a diagnostic data output gate coupled to the diagnostic data path which serves to gate off this output when the system is not in the diagnostic mode thereby avoiding the unnecessary consumption of energy by needlessly changing a voltage level associated with any circuit capacitance downstream of the diagnostic data output gate.

Viewed from another aspect the present invention provides a method of storing a signal value, said method comprising the steps of:
in an operational mode providing an operational clock signal having a first operational clock phase and a second operational clock phase;
receiving in an operational path latch of an operational data path a signal value during said second operational clock phase and storing said signal value during said first operational clock phase;
receiving in a shared latch coupled to said operational path latch said signal value during said first operational clock phase and storing said signal value during said second operational clock phase;
in a diagnostic mode providing a diagnostic clock signal having a first diagnostic clock phase and a second diagnostic clock phase;
receiving in a diagnostic path latch of a diagnostic data path a signal value during said second diagnostic clock phase and storing said signal value during said first diagnostic clock phase; and
receiving in said shared latch coupled to said diagnostic path latch said signal value during said first diagnostic clock phase and storing said signal value during said second diagnostic clock phase.

The above, and other objects, features and advantages of this invention will be apparent from the following detailed description of illustrative embodiments which is to be read in connection with the accompanying drawings.

### BRIEF DESCRIPTION OF THE DRAWINGS

FIG. 1 schematically illustrates a circuit for storing a signal value;

FIGS. 2, 3, 4 and 5 schematically illustrate the operation of the circuit of FIG. 1 in various modes and at various clock signal phases;

FIG. 6 schematically illustrates a second example embodiment of a circuit for storing a signal value;

FIG. 7 schematically illustrates a third example embodiment of a circuit for storing a signal value; and

FIG. 8 schematically illustrates a fourth example embodiment of a circuit for storing a signal value.

### DESCRIPTION OF THE PREFERRED EMBODIMENTS

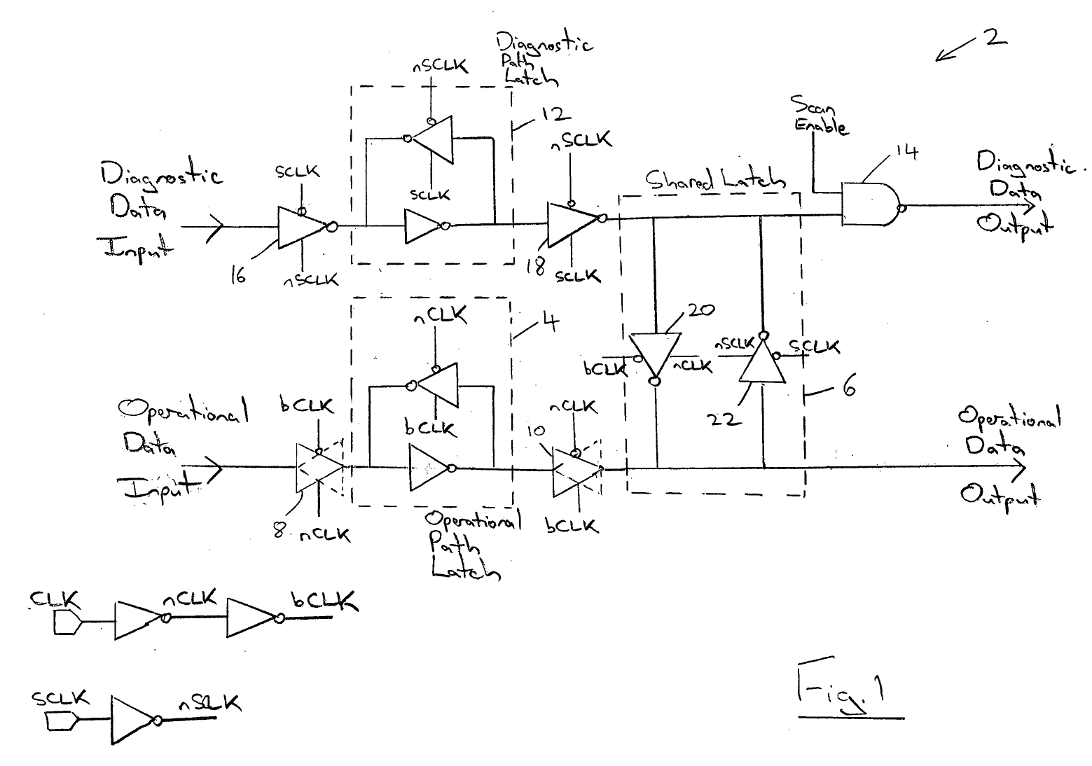

FIG. 1 illustrates a circuit 2 for storing a signal value. This circuit 2 includes an operational path latch 4 and a shared latch 6 both being disposed upon an operational data path between an operational data input and an operational data output. Transmission gates 8, 10 serve to control propagation of signal values along the operational data path. The transmission gates 8, 10 can also be considered to form part of their respective latches. The transmission gates 8, 10 can also be replaced by tri-stateable inverters or other tri-stateable drivers (more particularly, the transmission gate and driving cell can be replaced by a tri-state version of the driving cell. In particular, the input node of the transmission gate split with the PFRT driven by the driving PFET tree and the NFET driven by the driving NFET tree.)

The circuit 2 also includes a diagnostic data path between a diagnostic data input and a diagnostic data output and including a diagnostic path latch 12 and the shared latch 6. A diagnostic data output gate 14 which is selectively enabled by a scan enable signal SE serves to gate off the output of the diagnostic data path when the circuit 2 is not in the diagnostic mode. Tristate drivers 16, 18 serve to control the flow of signal values through the diagnostic data path (functionally equivalent alternative may also be used such as an inverter followed by a transmission gate).

An operational clock signal CLK serves to control the transmission gates 8, 10, the operational path latch 4 and one of the tristate drivers 20 within the shared latch 6. A diagnostic clock signal SCLK serves to control the tristate drivers 16, 18, the diagnostic path latch 12 and the other one of the tristate drivers 22 within the shared latch 6. As illustrated in the bottom portion of FIG. 1, clock signal nCLK and bCLK are derived from the signal CLK by passage through serially connected inverters (other arrangements are also possible as appropriate or desired). This inverter arrangement serves to reduce the load upon the basic CLK signal as well as ensuring a defined relative timing between the nCLK and bCLK signals. In a similar way a signal nSCLK is derived from the diagnostic clock signal SCLK by an inverter (a buffered version of SCLK may also be generated and used in a similar way as for CLK if desired).

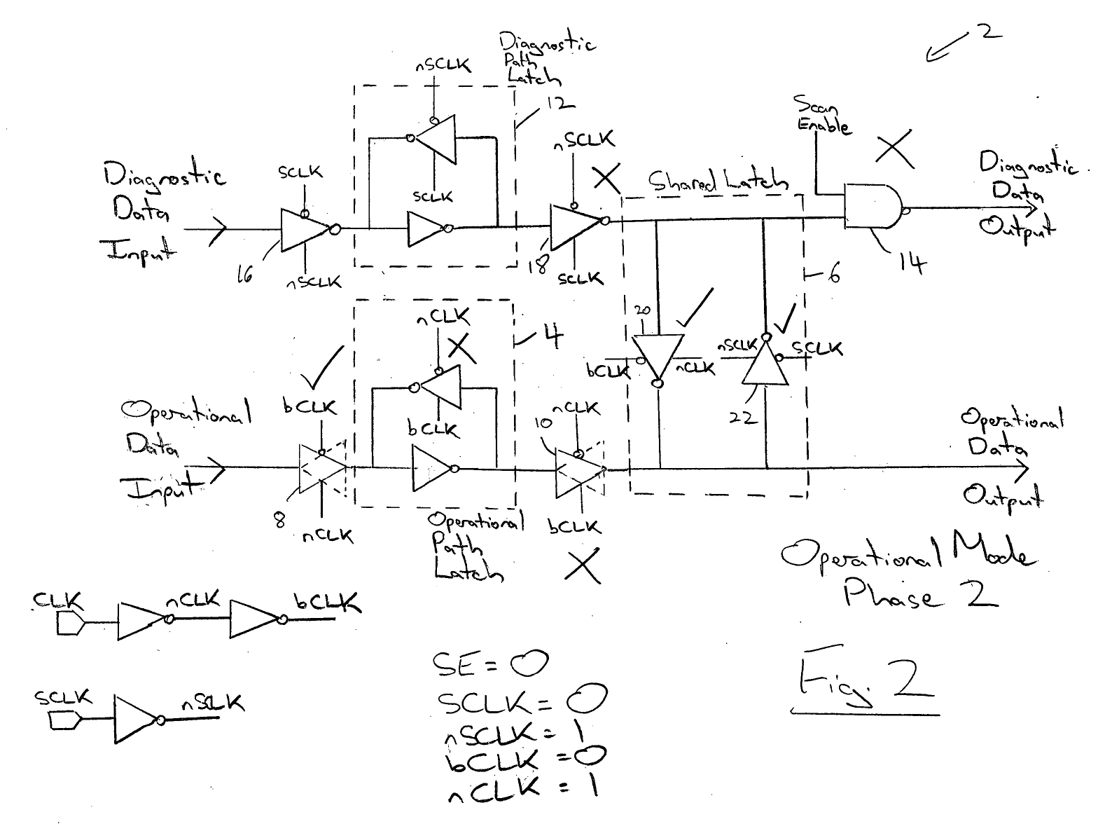

FIG. 2 schematically illustrates the operation of the circuit of FIG. 1 in Phase 2 of an operational mode. In this operational mode the diagnostic data output gate 14 is switched off by the scan enable signal SE having a low value. Within the operational data path in this second phase the transmission gate 8 is open whilst the transmission gate 10 is closed. Thus an operational data input signal value propagates through the transmission gate 8 into the operational path latch 4 and is then blocked by the transmission gate 10.

During the operational mode the diagnostic clock signal is constrained such that the value SCLK is held low throughout the operational mode. This ensures that the tristate driver 22 remains switched on during the operational mode. The tristate driver 20 of the shared latch 6 is selectively switched on and off by the operational clock signal CLK. In Phase 2 as illustrated in FIG. 2, the tristate driver 20 is switched on to enable the feedback loop around the shared latch 6 so that this positively holds its signal value and drives this out on the operational data output (possibly via one or more inverters serving to increase or appropriately adjust the output drive strength).

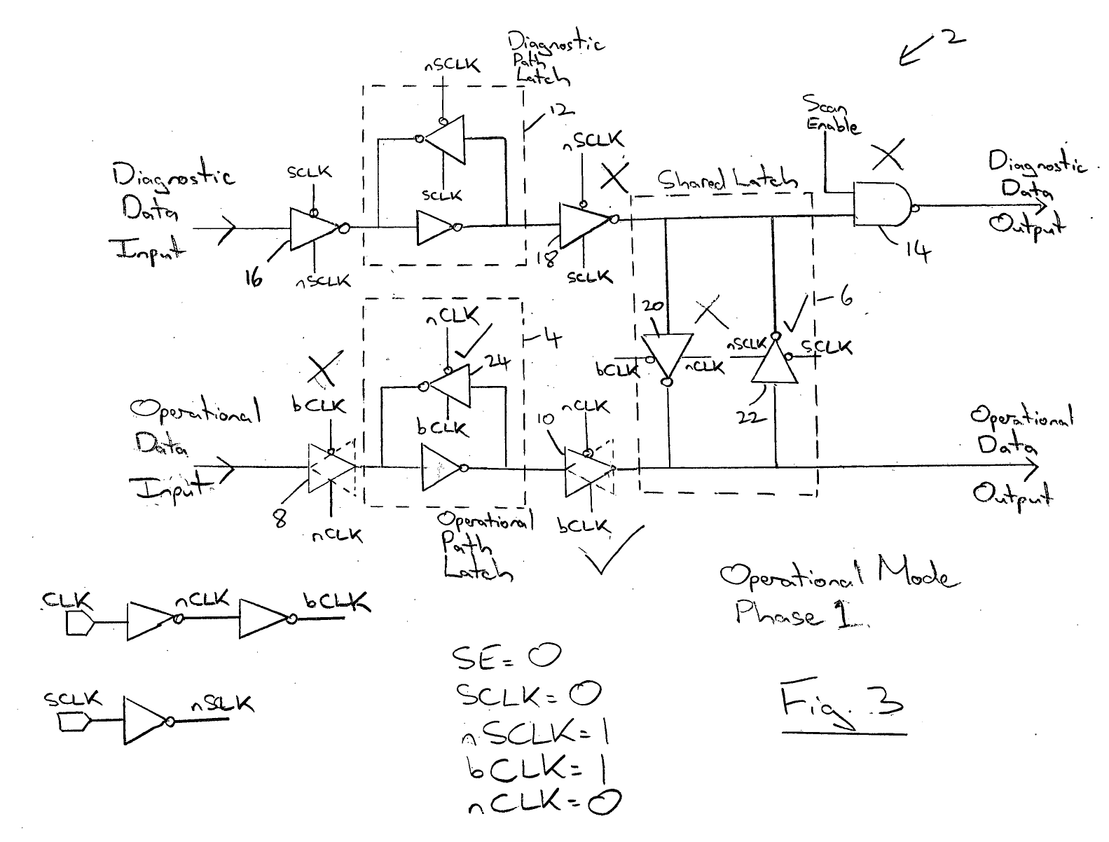

FIG. 3 illustrates the circuit 2 in the operational mode at Phase 1. In this state the diagnostic data output gate 14 remains closed. The transmission gate 8 is now closed whilst the transmission gate 10 is open. The tristate driver 24 within the operational path latch 4 is switched on thus enabling the feedback path around the operational path latch 4 so that it maintains its signal value. The transmission gate 10 drives the signal value output from the operational path latch 4 out to the operational data output as well as through the tristate driver 22 which is permanently enabled during the operational mode by the static value of the diagnostic clock signal SCLK. The tristate driver 20 is disabled during Phase 1 as it is not required to hold the data value within the shared latch 6 and this also avoids the possibility of contention.

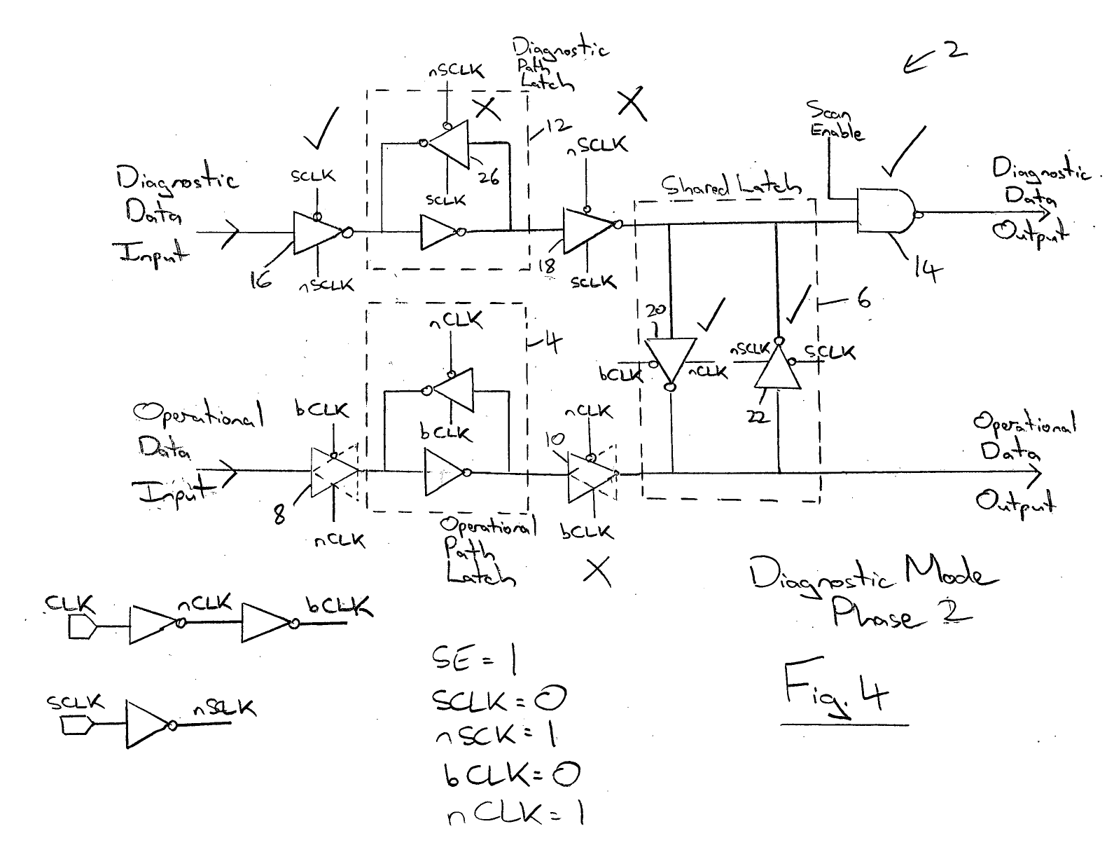

FIG. 4 illustrates the circuit 2 in Phase 2 of the diagnostic mode of operation. In this mode the diagnostic data output gate 14 is enabled. The transmission gate 10 is disabled by the static value of the operational clock signal CLK which is held during the diagnostic mode such that bCLK is held low. In a similar way the tristate driver 18 is held off during both phases of the operational mode as illustrated in FIGS. 2 and 3.

In this Phase 2 of the diagnostic mode, the two tristate drivers 20, 22 within the shared latch 6 are enabled such that feedback occurs around the shared latch 6 and the signal value stored therein is output through the diagnostic data output gate 14 to the diagnostic data output. At the same time the tristate driver 16 is open allowing diagnostic data input signals to pass into the diagnostic path latch 12. The tristate driver 26 within the diagnostic path latch 12 is disabled during this second phase of the diagnostic mode since it is not required and to avoid contention.

It will be appreciated that the diagnostic data input and the diagnostic data output may respectively be coupled to preceding and succeeding similar circuits for storing a signal value so as to collectively form a serial scan chain (not illustrated) path through which diagnostic data may be serially scanned into and out of an integrated circuit.

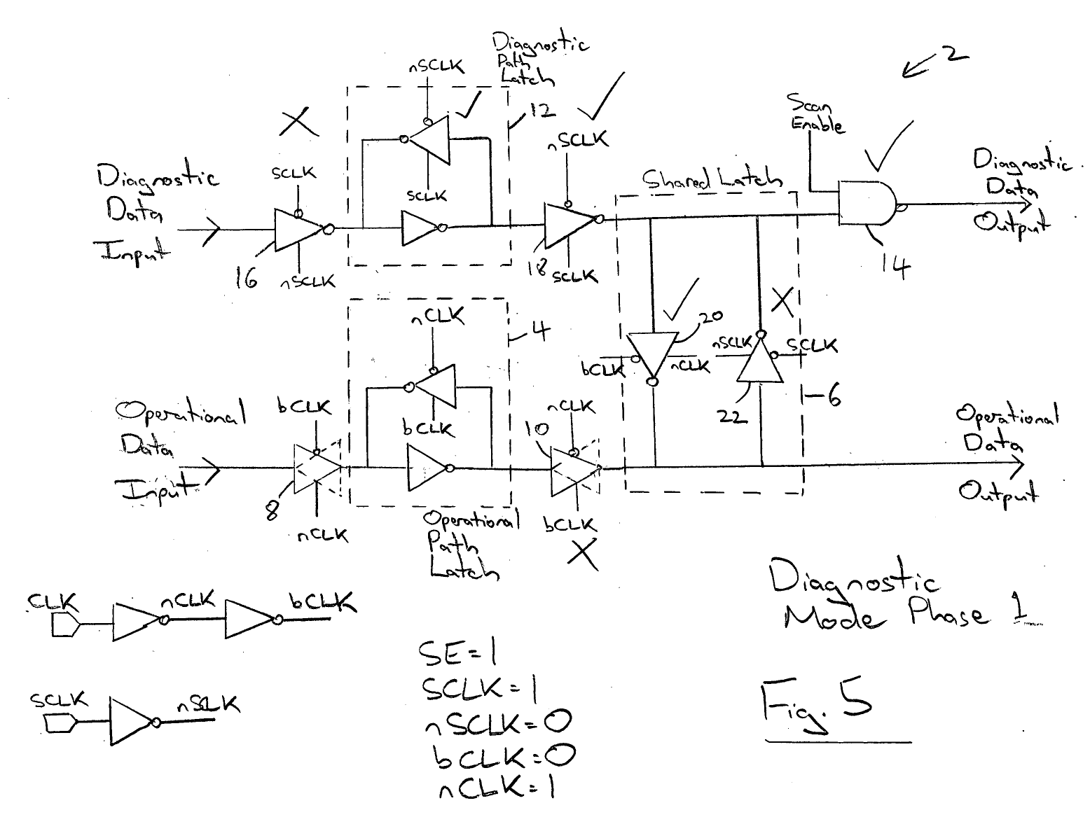

FIG. 5 illustrates the circuit 2 during Phase 1 of the diagnostic mode. In this phase the transmission gate 10 within the operational data path remains closed. The tristate driver 16 is now closed whilst the feedback within the diagnostic path latch 12 is enabled such that the diagnostic path latch 12 positively holds its signal value. The tristate driver 18 is open allowing the signal value stored within the diagnostic path latch to be driven out to the diagnostic data output through the diagnostic data output gate 14 and also into the shared latch 6. Feedback is not required around the shared latch 6 during this first phase of the diagnostic mode and would be undesirable since it would cause contention.

It will be appreciated that the circuit 2 illustrated in FIGS. 1 to 5 does not include a separate multiplexer at its input. The respective data paths are effectively selected through control of the clock signals with a defined relationship between the diagnostic clock signal and the operational clock signal with these being held at predetermined values whilst the other is active. The shared latch 6 is part of both the diagnostic data path and the operational data path thereby advantageously reducing gate count. Furthermore, a signal value held within the shared latch is automatically passed between the operational data path and the diagnostic data path when the circuitry 2 switches between the operational mode and the diagnostic mode.

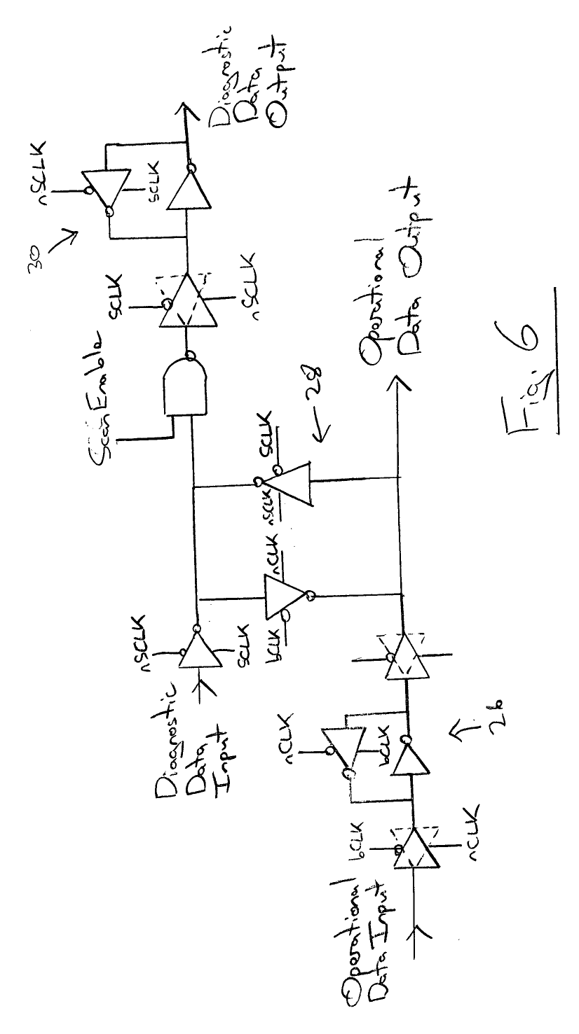

FIG. 6 illustrates a second example embodiment of a circuit for storing a signal value. In this embodiment the operational data path is formed by an operational latch 26 followed by a shared latch 28. The diagnostic data path is formed by the shared latch 28 followed by a diagnostic path latch 30. The operation of the circuit of FIG. 6 is similar to that previously described with the diagnostic clock signal being held static at a predetermined value during the operational mode when the operational clock is varying and vice versa.

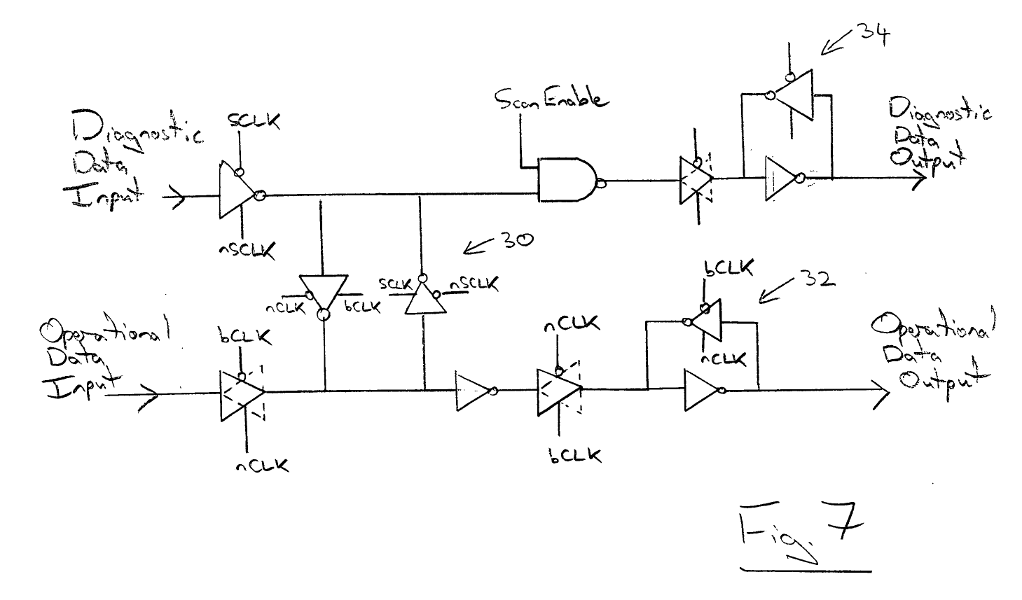

FIG. 7 illustrates a third example embodiment of a circuit for storing a signal value. In this third example the operational data path is formed by a shared latch 30 followed by an operational path latch 32. The diagnostic data path is formed by the shared latch 30 followed by a diagnostic path latch 34.

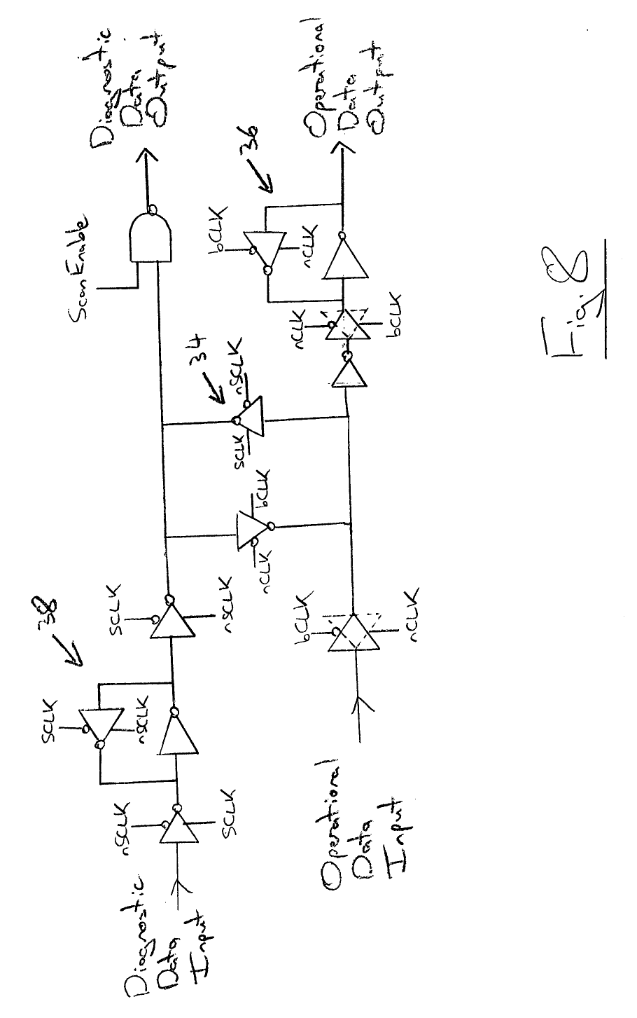

FIG. 8 schematically illustrates a fourth example embodiment of a circuit for storing a signal value. In this fourth example embodiment the operational data path is formed by a shared latch 34 followed by an operational path latch 36. The diagnostic data path is formed by a diagnostic path latch 38 followed by the shared latch 34.

Although illustrative embodiments of the invention have been described in detail herein with reference to the accompanying drawings, it is to be understood that the invention is not limited to those precise embodiments, and that various changes and modifications can be effected therein by one skilled in the art without departing from the scope and spirit of the invention as defined by the appended claims.

1. A circuit for storing a signal value, said circuit comprising:
an operational clock signal source operable in an operational mode to provide an operational clock signal having a first operational clock phase and a second operational clock phase;
an operational data path including:
an operational path latch operable to receive a signal value during said second operational clock phase and to store said signal value during said first operational clock phase; and
a shared latch coupled to said operational path latch and operable to receive said signal value during said first operational clock phase and to store said signal value during said second operational clock phase;
a diagnostic clock signal source operable in a diagnostic mode to provide a diagnostic clock signal having a first diagnostic clock phase and a second diagnostic clock phase; and
a diagnostic data path including:
a diagnostic path latch operable to receive a signal value during said second diagnostic clock phase and to store said signal value during said first diagnostic clock phase; and
said shared latch coupled to said diagnostic path latch and operable to receive said signal value during said first diagnostic clock phase and to store said signal value during said second diagnostic clock phase.

2. A circuit as claimed in claim 1, wherein said shared latch receives said signal value from said operational data path latch.

3. A circuit as claimed in claim 1, wherein said operational data path latch receives said signal value from said shared latch.

4. A circuit as claimed in claim 1, wherein said shared latch receives said signal value from said diagnostic data path latch.

5. A circuit as claimed in claim 1, wherein said diagnostic data path latch receives said signal value from said shared latch.

6. A circuit as claimed in claim 1, wherein said shared latch comprises a first tristate driver selectively enabled by said operational clock signal and a second tristate driver selectively enabled by said diagnostic clock signal.

7. A circuit as claimed in claim 1, wherein said operational clock signal is held static when said diagnostic clock signal is active and said diagnostic clock signal is held static when said operational clock signal is active.

8. A circuit as claimed in claim 1, wherein said diagnostic data path is part of a serial scan chain for serially scanning diagnostic data through an integrated circuit.

9. A circuit as claimed in claim 1, comprising a diagnostic data output gate coupled to said diagnostic data path so as to receive diagnostic data from said diagnostic data path, said diagnostic data output gate being operable when a scan enable signal indicates that said diagnostic clock signal is inactive to block signal value changes being output from said diagnostic data path.

10. A method of storing a signal value, said method comprising the steps of:
in an operational mode providing an operational clock signal having a first operational clock phase and a second operational clock phase;
receiving in an operational path latch of an operational data path a signal value during said second operational clock phase and storing said signal value during said first operational clock phase;
receiving in a shared latch coupled to said operational path latch said signal value during said first operational clock phase and storing said signal value during said second operational clock phase;
in a diagnostic mode providing a diagnostic clock signal having a first diagnostic clock phase and a second diagnostic clock phase;
receiving in a diagnostic path latch of a diagnostic data path a signal value during said second diagnostic clock phase and storing said signal value during said first diagnostic clock phase; and
receiving in said shared latch coupled to said diagnostic path latch said signal value during said first diagnostic clock phase and storing said signal value during said second diagnostic clock phase.

11. A method as claimed in claim 10, wherein said shared latch receives said signal value from said operational data path latch.

12. A method as claimed in claim 10, wherein said operational data path latch receives said signal value from said shared latch.

13. A method as claimed in claim 10, wherein said shared latch receives said signal value from said diagnostic data path latch.

14. A method as claimed in claim 10, wherein said diagnostic data path latch receives said signal value from said shared latch.

15. A method as claimed in claim 10, wherein said shared latch comprises a first tristate driver selectively enabled by said operational clock signal and a second tristate driver selectively enabled by said diagnostic clock signal.

16. A method as claimed in claim 10, wherein said operational clock signal is held static when said diagnostic clock signal is active and said diagnostic clock signal is held static when said operational clock signal is active.

17. A method as claimed in claim 10, wherein said diagnostic data path is part of a serial scan chain for serially scanning diagnostic data through an integrated circuit.

18. A method as claimed in claim 10, comprising a diagnostic data output gate coupled to said diagnostic data path so as to receive diagnostic data from said diagnostic data path, said diagnostic data output gate being operable when a scan enable signal indicates that said diagnostic clock signal is inactive to block signal value changes being output from said diagnostic data path.
